(19) United States
(12) Patent Application Publication
(10) Pub. No.: US 2009/0239085 A1
(43) Pub. Date: Sep. 24, 2009

(54) SiC SEMICONDUCTOR ELEMENT, METHOD OF MANUFACTURING THE SAME, AND MANUFACTURING APPARATUS THEREOF

(76) Inventor: Toshihiro Ehara, Saitama (JP)

Correspondence Address: WILMERHALE/DC, 1875 PENNSYLVANIA AVE., NW, WASHINGTON, DC, 20006, US

(21) Appl. No.: 12/394,536

(22) Filed: Feb. 27, 2009

(30) Foreign Application Priority Data
Mar. 24, 2008 (JP) 2008-075731

(51) Int. Cl. B32B 9/04; C23C 16/32; H01L 21/20

(52) U.S. Cl. 428/446; 118/715; 438/478; 257/E21.09

(57) ABSTRACT

A method of manufacturing a silicon carbide semiconductor element by using a chemical vapor growth method is provided. The method includes supplying a source gas comprising silicon and carbon and an impurity radical on a substrate so as to form a silicon carbide layer on the substrate, the silicon carbide layer including silicon carbide and an impurity that binds covalently to the silicon carbide.

### CROSS-REFERENCE TO RELATED APPLICATIONS

This application is based upon and claims priority from Japanese Patent Application No. 2008-075731 filed on Mar. 24, 2008, the entire contents of which are incorporated herein by reference.

### BACKGROUND OF THE INVENTION

1. Technical Field

The present invention relates to a semiconductor device including a SiC semiconductor layer and, in particular, to a semiconductor device which is used, for example, as a power semiconductor device, a method of manufacturing the same, and a manufacturing apparatus thereof.

2. Description of the Related Art

SiC (silicon carbide) has: an energy gap two to three times larger than a general semiconductor material such as Si (silicon) and GaAs (gallium arsenide); and a breakdown electric field about one digit larger than that of the general semiconductor material. Therefore, SiC is expected to be used for the high-voltage power semiconductor device instead of Si that has become mainstream.

In order to manufacture the SiC semiconductor device, an SiC single-crystal substrate is manufactured by using a typical method such as an Acheson method, a modified Lely method, a CVD (chemical vapor growth) method, etc. In the Acheson method, an SiC seed crystal plate is obtained by reaction of SiO₂ (silicon dioxide) and C (coke) at a temperature of 2000° C. or more. In the modified Lely method, the SiC single-crystal substrate is obtained by: subliming SiC powder in a crucible; and condensing and growing the resulting vapor of Si and C on the SiC seed crystal plate. In the CVD method, the SiC single-crystal substrate is obtained by: supplying source gases including Si and C respectively to a reactor in which the SiC seed crystal plate is disposed; and growing a SiC crystal on the SiC seed crystal plate.

In manufacturing the SiC semiconductor device, it is absolutely necessary that an impurity is introduced into the semiconductor layer in order to arbitrarily control the on-resistance and a breakdown voltage of the semiconductor device. For a Si semiconductor layer, an introducing method such as a thermal diffusion of the impurity material or an ion implantation is generally adopted. The SiC semiconductor layer is also attempted to adopt these methods but the good impurity SiC layer is not able to be obtained. In connection with the thermal diffusion, since a diffusion coefficient of the impurity of the SiC layer under low temperature (about 1500° C. or less) is lowered, it causes that the impurity is difficult to be introduced into the SiC layer, and the impurity SiC layer is not obtained with an arbitrary impurity concentration and an arbitrary depth. In connection with the ion implantation, since crystal defects generated inside the SiC layer by the implantation cannot be sufficiently restored in an annealing process but remains, it causes that a characteristic such as a leakage current or the like is deteriorated. These disadvantages cause a difficulty in manufacturing the SiC semiconductor device, in particular, in introducing the p-type impurity.

Here, a method of obtaining the high concentration p-type SiC layer by using the sublimation method or the CVD method and the annealing process is studied. In the sublimation method, the SiC crystal introduced with p-type impurity atoms are condensed and grown on the semiconductor substrate by mixing the SiC powder and the p-type impurity such as Al (aluminum) and B (boron) in the crucible as used in the modified Lely method and by subliming the mixed one. In addition, in the CVD method, the source gases including Si and C respectively, and a p-type impurity gas such as TMA (trimethylaluminium), B₂H₆ (diborane), BCl₃ (boron trichloride), or the like are fed into the reactor and are subjected to a thermal decomposition reaction under environment of a normal pressure or a reduced pressure, and thereby growing the SiC crystal introduced with the p-type impurity atoms on the semiconductor substrate. Then, activating of the p-type impurity and restoring of the crystal defects are executed by the annealing process.

However, in the p-type SiC layer obtained by the sublimation method and the CVD method described above, an activation rate of the impurity is lowered. That is, even though the introduced impurity atoms does not function as an acceptor as long as Si and C does not bind covalently, a large number of the impurity atoms exist as independent atoms in the SiC crystal. For this reason, even though the introduced impurity concentration is increased, a sheet resistance of the p-type SiC layer cannot be decreased, so that the p-type SiC layer becomes a cause of increase in power loss of the SiC semiconductor device.

JP-B-3650727 describes a technique for increasing the activation rate of the impurity in the CVD method. This CVD method will be described with reference to FIG. 5. In this CVD method, a apparatus for manufacturing a semiconductor device includes a reaction unit 501, a gas supply unit 502, and an exhaust unit 503. The reaction unit 501 includes a reactor 511, a substrate holder 512 provided in the reactor 511 on which a semiconductor substrate 513 is disposed, and a heating device 514 which heats the semiconductor substrate 513. The gas supply unit 502 includes a gas feeding tube 521 whose one end is connected to the reactor 511, gas supply sources 522 to 525 which are connected to the other end of the gas feeding tube 521 and supply source gases different from one another. The exhaust unit 503 includes an exhaust tube 531 whose one end is connected to the reactor 511.

In this CVD method, the semiconductor substrate 513 is heated up to a constant temperature by using the heating device 514, a pressure in the reactor 511 is maintained by controlling the exhaust unit 503, and an H₂ (hydrogen) gas is continuously supplied to the reactor 511 from the H₂ supply source 522. At the same time, a process for continuously or intermittently supplying a SiH₂Cl₂ (dichlorosilane) gas and a BCl₃ gas to the reactor 511 from the SiH₂Cl₂ supply source 523 and the BCl₃ supply source 524, intermittently supplying a C₂H₂ (acetylene) gas to the reactor 511 from the C₂H₂ supply source 525 is repeated. Accordingly, the SiC crystal layer introduced with the p-type impurity is grown on the semiconductor substrate 513.

According to the method, by controlling the gas supply from the gas supply sources 522 to 525 such that a process of adding the impurity by using the BCl₃ gas and a process of carbonizing by using the C₂H₂ gas are alternately executed, the impurity atoms are easily replaced to a Si site in the SiC crystal. In addition, the high concentration p-type SiC layer is obtained through activation processing of the impurity by the annealing process.

However, in this CVD method, controlling the gas supply source becomes complicated because the gas supply is intermittently executed. In addition, since the annealing process is required due to the activation processing of the impurity, the process is cumbersome.

### BRIEF SUMMARY OF THE INVENTION

The present invention was made in consideration of the above-described circumstances, and an object thereof is to form a high concentration p-type SiC layer through a simple manufacturing method, and to obtain a semiconductor device with low on-resistance.

According to an aspect of the invention, there is provided a method of manufacturing a silicon carbide semiconductor element by using a chemical vapor growth method, said method comprising: supplying a source gas comprising silicon and carbon and an impurity radical on a substrate so as to form a silicon carbide layer on the substrate, the silicon carbide layer comprising silicon carbide and an impurity that binds covalently to the silicon carbide.

According to another aspect of the invention, there is provided an apparatus for manufacturing a semiconductor element by forming a semiconductor layer on a substrate by using a chemical vapor growth method, said apparatus comprising: a reactor in which the substrate is disposed; a source gas feeding tube which supplies a source gas comprising silicon and carbon to the reactor; and a radical feeding tube which feeds an impurity radical to the reactor.

According to yet another aspect of the invention, there is provided a semiconductor element comprising: a semiconductor substrate; and a silicon carbide layer of a first conductive type formed on the semiconductor substrate, wherein the silicon carbide layer comprises silicon carbide and an impurity radical that binds covalently to the silicon carbide.

### BRIEF DESCRIPTION OF THE DRAWING

FIG. 1 is a diagram schematically illustrating a configuration of a manufacturing apparatus according to a first embodiment of the present invention;

FIG. 2 is a diagram schematically illustrating a configuration of a manufacturing apparatus according to a second embodiment of the present invention;

FIG. 3 is a cross-sectional view illustrating a configuration of a semiconductor device according to an embodiment of the present invention;

FIGS. 4A to 4D are cross-sectional views illustrating respective processes of a manufacturing method of the semiconductor device shown in FIG. 3; and

FIG. 5 is a view schematically illustrating a configuration of a related-art CVD method.

### DETAILED DESCRIPTION OF THE EMBODIMENT

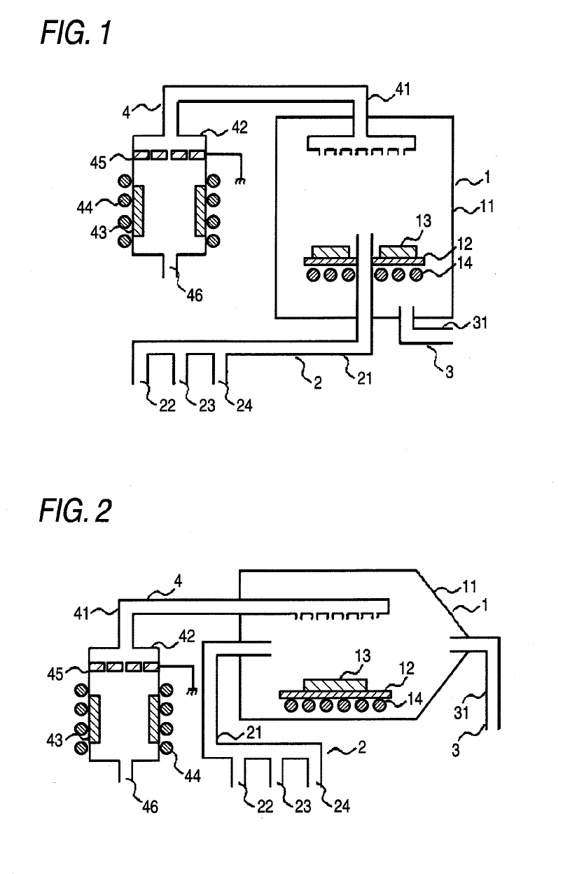

Next, an example of a manufacturing method according to the embodiment of the present invention will be described with reference to FIGS. 1 and 2.

FIG. 1 shows a diagram schematically illustrating a configuration of the manufacturing apparatus according to a first embodiment of the present invention.

The manufacturing apparatus according to the first embodiment includes: a reaction unit 1; a gas supply unit 2; an exhaust unit 3; and a radical supply unit 4. The reaction unit 1 includes: a reactor 11; a substrate holder 12 provided in the reactor 11, on which a semiconductor substrate 13 can be disposed; and a heating device 14 configured to heat the semiconductor substrate 13. The gas supply unit 2 includes: a gas feeding tube 21 whose one end is connected to the reactor 11; gas supply sources 22 to 24 which are connected to the other end of the gas feeding tube 21. The exhaust unit 3 includes an exhaust tube 31 whose one end is connected to the reactor 11. The radical supply unit 4 includes: a radical feeding tube 41 whose one end is connected to the reactor 11; a radical generating unit 42 which is connected with the other end of the radical feeding tube 41 and includes a plasma generating unit 43, a heating device 44, and an ion/radical separating device 45; and an impurity gas supply source 46 connected to the radical generating unit 42.

That is, as described above, the manufacturing apparatus according to the first embodiment of the present invention includes the radical supply unit 4 connected to the reaction unit 1.

Next, a method of manufacturing the high concentration p-type SiC layer according to the first embodiment of the present invention will be described.

In the radical supply unit 4, the TMA is supplied from the impurity gas supply source 46 to the radical generating unit 42. The radical generating unit 42, the TMA is decomposed and excited by plasma generated by micro waves supplied to the plasma generating unit 43 and by heat generated by the heating device 44, and thus activating particles such as Al⁻³ (ion) and Al* (radical) are generated. The activating particles are sent from the radical generating unit 42 to the radical feeding tube 41, but Al⁻³ is trapped by the ion/radical separating device 45, and thus only Al* is supplied to the reactor 11 through the radical feeding tube 41.

That is, in the manufacturing method according to the first embodiment of the present invention, the impurity radical obtained by exiting the impurity gas is supplied to the reactor 11.

The radical is an atom or a molecule in which one electron exists on electron orbits, and is also called as a free radical. Even though a general atom or molecule has electrons paired with each other, the radical can be generated such that the atom or the molecule is excited by the plasma as described above and loses the electrons, for example. Since the radical has a significantly high reactive property between non-radical species such as other atoms and molecules, Al* supplied to the reactor 11 reacts with the atoms or the molecules of Si and C in the source gas in a vapor state and forms a covalent bonding.

One example of the ion/radical separating device 45 a grounded conductive metal plate made of a material such as Cu, Ag, Au, or Al, and a through hole such as a slit or a pinhole formed therein. However, the ion/radical separating device 45 may include positive and negative electrodes in which a direct current or an alternative current flows. In both structures, the radial can be separated from the ion by using an electrical property that the radical has electrical neutrality but the ions have charges. Accordingly, Al* can be supplied to the reactor 11.

According to the manufacturing method of the first embodiment of the present invention, the following advantages can be obtained.

(1) The silicon carbide is precipitated on the semiconductor substrate 13 after Al* covalently binds to the source gas, that is, the impurity is in an activated state. Consequently, there is no need for the annealing process for the activation processing. Therefore, the manufacturing process can be simplified.

(2) The supplying path of the radical including the radical feeding tube 41 can suppress the reaction of Al* with other non-radical species, the activation rate of the impurity is high, and it contributes to the improved characteristics and reliability of the semiconductor device.

(3) Since the CVD method is used, the high concentration p-type SiC layer can be obtained regardless of the types (Si, SiC, GaN, or the like) or the crystal system of the semiconductor substrate 13.

FIG. 2 shows a diagram schematically illustrating a configuration of a manufacturing apparatus according to a second embodiment of the present invention. The manufacturing apparatus according to the second embodiment is different from that of the first embodiment in that the reaction unit 1 has a vertical structure, and the others are formed in the same configuration. However, the same advantages as that of the first embodiment can be obtained.

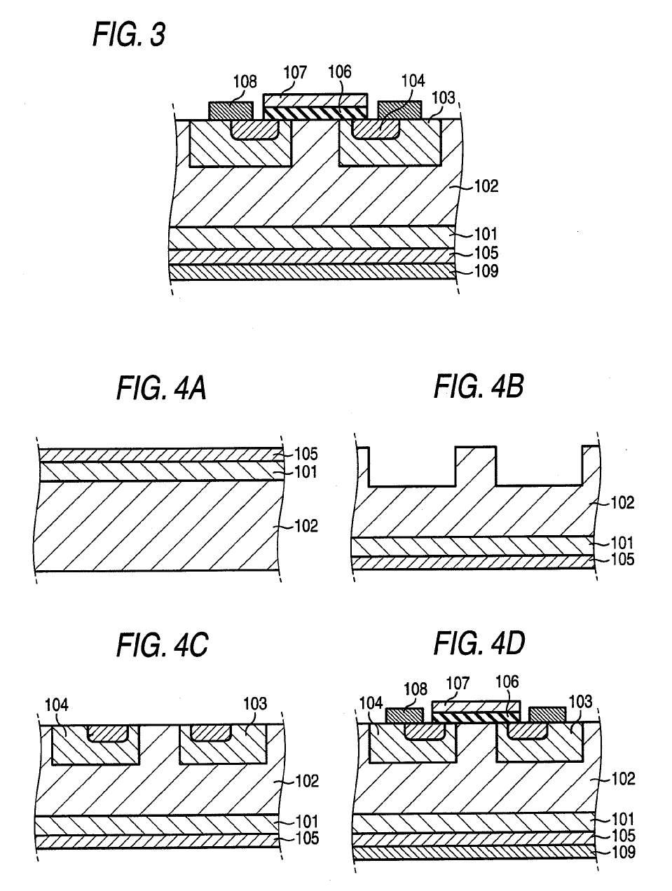

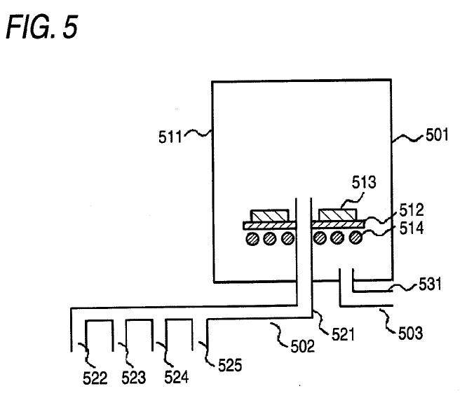

Next, an example of the semiconductor device according to the embodiment of the present invention will be described with reference to FIGS. 3 and 4.

FIG. 3 is a cross-sectional view illustrating an IGBT (Insulated Gate Bipolar Transistor) having the high concentration p-type SiC layer which is manufactured through the manufacturing method according to the embodiment of the present invention, and FIGS. 4A to 4D are cross-sectional views illustrating respective processes of the manufacturing method thereof.

The IGBT according to the embodiment of the present invention includes: a high concentration n-type semiconductor substrate 101; a low concentration n-type epitaxial layer 102; a p-type base layer 103; a n-type emitter layer 104; a high concentration p-type SiC layer 105; a gate oxide film 106 containing SiO₂; a gate electrode 107 containing polysilicon; an emitter electrode 108 including Ti/TiN/Al laminated structure; and a collector electrode 109 containing Ni.

Next, the method of manufacturing the IGBT according to the embodiment of the present invention will be described.

As shown in FIG. 4A, the high concentration p-type SiC layer 105 is formed on the semiconductor substrate 101 by the manufacturing method according to the embodiments of the present invention.

Next, as shown in FIG. 4B, a part of the epitaxial layer 102 is removed by the dry etching or the wet etching, and damage by the etching is removed.

Next, as shown in FIG. 4C, the base layer 103 is formed by the CVD method. In this process, the well-known CVD is applicable. In addition, the emitter layer 104 is formed by: implantation of the n-type impurity on a position at which the emitter layer 104 is formed on the base layer 103; and performing the activation by the annealing.

Then, as shown in FIG. 4D, after the gate oxide film 106 is formed on the epitaxial layer 102, the gate layer 103, and the emitter layer 104 by using the CVD method, the gate electrode 107 is formed on the gate oxide film 106, and the emitter electrode 108 and the collector electrode 109 are formed.

According to the IGBT of the embodiment of the present invention, since the high concentration p-type SiC layer 105 is provided, the power semiconductor device using SiC which can have the high breakdown voltage and the low on-resistance. The manufacturing method of the embodiments of the present invention is applicable in a wide range of various devices other than the semiconductor device or the IGBT which does not use SiC.

The present invention is not limited to the above-mentioned embodiments. For example, the following modifications can be made.

(1) The manufacturing method of the embodiments of the present invention may be applicable to the SiC layer formation including the n-type impurity.

(2) The reactor 11 may have a structure used in the well-known CVD method such as a diffusion furnace.

(3) The substrate holder 12, the gas feeding tube 21, and the radical feeding tube 41 may be provided to have a different angle between one another according to the required reaction or the crystal growth. In addition, the substrate holder 12 may be configured to be rotated in the reactor 11.

(4) Excitation means of the impurity gas is not limited to the plasma, and heat, light, laser, or the like may be used.

(5) A generation principle of the plasma generating unit 43 may be excited by using RF (high frequency) or VHF (very high frequency) according to the impurity gas to be supplied.

(6) The separation method of the ion/radical separating device 45 is not limited to an electrical one, and may be a method using a chemical reaction.

(7) In the method of manufacturing the IGBT, the base layer 103 may be formed on the epitaxial layer 102 through the ion implantation of p-type impurity and the annealing without performing the etching.

According to the embodiments of the present invention, the high concentration p-type SiC layer can be formed through the simple manufacturing method, and a semiconductor device with a low on-resistance is obtained.

What is claimed is:

1. A method of manufacturing a silicon carbide semiconductor element by using a chemical vapor growth method, said method comprising:
supplying a source gas comprising silicon and carbon and an impurity radical on a substrate so as to form a silicon carbide layer on the substrate, the silicon carbide layer comprising silicon carbide and an impurity that binds covalently to the silicon carbide.

2. The method according to claim 1, comprising:
disposing the substrate in a reactor;
supplying the source gas comprising silicon and carbon and the impurity radical to the reactor; and
forming the silicon carbide layer of the first conductive type on the substrate.

3. The method according to claim 2, comprising precipitating the silicon carbide of the first conductive type which binds covalently to the impurity in a vapor state.

4. The method according to claims 1,
wherein the first conductive type is a p type.

5. An apparatus for manufacturing a semiconductor element by forming a semiconductor layer on a substrate by using a chemical vapor growth method, said apparatus comprising:
a reactor in which the substrate is disposed;
a source gas feeding tube which supplies a source gas comprising silicon and carbon to the reactor; and
a radical feeding tube which feeds an impurity radical to the reactor.

6. The apparatus according to claim 5, further comprising:
a radical generating unit which generates the impurity radical by exciting an impurity gas,
wherein the radical generating unit is connected to the reactor via the radical feeding tube.

7. The apparatus according to claim 6,
wherein the radical generating unit comprises a separating device which separates the impurity radical and ions.

8. A semiconductor element comprising:
a semiconductor substrate; and
a silicon carbide layer of a first conductive type formed on the semiconductor substrate,
wherein the silicon carbide layer comprises silicon carbide and an impurity radical that binds covalently to the silicon carbide.
